(19) United States
(12) Patent Application Publication
(10) Pub. No.: US 2025/0301747 A1
(43) Pub. Date: Sep. 25, 2025

(54) TRANSISTOR

(71) Applicant: InnoLux Corporation, Miao-Li County (TW)

(72) Inventor: Jhe-Ciou JHU, Miao-Li County (TW)

(73) Assignee: InnoLux Corporation, Miao-Li County (TW)

(21) Appl. No.: 19/057,943

(22) Filed: Feb. 19, 2025

(30) Foreign Application Priority Data
Mar. 22, 2024 (CN) 202410332521.0

(51) Int. Cl. H10D 64/00; H10D 30/67

(52) U.S. Cl. CPC H10D 64/111; H10D 30/6755; H10D 30/6757

(57) ABSTRACT

A transistor including a substrate, an oxide semiconductor layer, a gate metal pattern, a source/drain metal pattern and a field induced metal pattern is disclosed. The oxide semiconductor layer is disposed on the substrate and includes a first region, a second region and a third region, and the second region is disposed between the first region and the third region. When the transistor is turned off, an impedance of the first region is greater than that of the second region, and that of the second region is greater than that of the third region. The gate metal pattern is disposed on the substrate and overlapped with the first region. The source/drain metal pattern is disposed on the oxide semiconductor layer and overlapped with the third region. The field induced metal pattern is disposed on the substrate and overlapped with the second region but not overlapped with the first region.

### BACKGROUND OF THE DISCLOSURE

### 1. Field of the Disclosure

The present disclosure relates to a transistor, and more particularly to a transistor including an oxide semiconductor layer.

### 2. Description of the Prior Art

With the progress of science and technology, electronic devices have become indispensable items in modern life, wherein transistors are widely used in various electronic devices as switching elements or driving elements. However, in the operating condition of high electric field or high voltage, transistors are easily deteriorated or damaged.

### SUMMARY OF THE DISCLOSURE

One of the objectives of the present disclosure is to provide a transistor, so as to solve the problems encountered by the conventional transistors, wherein through the specific layer-stacking design, the partial regional impedance of the oxide semiconductor layer may be adjusted, thereby improving the effect of dispersing the voltage on the oxide semiconductor layer in the high electric field or high voltage environment, such that the withstand voltage performance of the transistor may be improved.

The present disclosure provides a transistor including a substrate, an oxide semiconductor layer, a gate metal pattern, a source metal pattern or a drain metal pattern, and a field induced metal pattern. The oxide semiconductor layer is disposed on the substrate and includes a first region, a second region and a third region, and the second region is disposed between the first region and the third region. When the transistor is turned off, an impedance of the first region is greater than an impedance of the second region, and the impedance of the second region is greater than an impedance of the third region. The gate metal pattern is disposed on the substrate and overlapped with the first region. The source metal pattern or the drain metal pattern is disposed on the oxide semiconductor layer and overlapped with the third region. The field induced metal pattern is disposed on the substrate. The field induced metal pattern is overlapped with the second region, but not overlapped with the first region nor the third region.

The present disclosure further provides a transistor including a substrate, an oxide semiconductor layer, a gate metal pattern, and a source metal pattern or a drain metal pattern. The oxide semiconductor layer is disposed on the substrate and includes a first region, a second region and a third region, and the second region is disposed between the first region and the third region. When the transistor is turned off, an impedance of the first region is greater than an impedance of the second region, and the impedance of the second region is greater than an impedance of the third region. The gate metal pattern is disposed on the substrate and overlapped with the first region and the second region. The source metal pattern or the drain metal pattern is disposed on the oxide semiconductor layer and overlapped with the third region. The minimum distance between the first region of the oxide semiconductor layer and the gate metal pattern is defined as a first distance, the minimum distance between the second region of the oxide semiconductor layer and the gate metal pattern is defined as a second distance, and the first distance is less than the second distance.

The present disclosure further provides a transistor including a substrate, an oxide semiconductor layer, a gate metal pattern, and a source metal pattern or a drain metal pattern. The oxide semiconductor layer is disposed on the substrate and includes a first region, a second region and a third region, and the second region is disposed between the first region and the third region. When the transistor is turned off, an impedance of the first region is greater than an impedance of the second region, and the impedance of the second region is greater than an impedance of the third region. The gate metal pattern is disposed on the oxide semiconductor layer and overlapped with the first region. The source metal pattern or the drain metal pattern is disposed on the oxide semiconductor layer and overlapped with the third region. The first region of the oxide semiconductor layer has a first thickness, the second region of the oxide semiconductor layer has a second thickness, and the first thickness is greater than the second thickness.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 is a cross-sectional schematic diagram of a transistor according to a first embodiment of the present disclosure.

FIG. 2 is a cross-sectional schematic diagram of a transistor according to a variant embodiment of a first embodiment of the present disclosure.

FIG. 3 is a cross-sectional schematic diagram of a transistor according to a second embodiment of the present disclosure.

FIG. 4 is a cross-sectional schematic diagram of a transistor according to a variant embodiment of a second embodiment of the present disclosure.

FIG. 5 is a cross-sectional schematic diagram of a transistor according to a third embodiment of the present disclosure.

FIG. 6 is a cross-sectional schematic diagram of a transistor according to a variant embodiment of a third embodiment of the present disclosure.

FIG. 7 is a cross-sectional schematic diagram of a transistor according to a fourth embodiment of the present disclosure.

FIG. 8 is a cross-sectional schematic diagram of a transistor according to a variant embodiment of a fourth embodiment of the present disclosure.

FIG. 9 is a cross-sectional schematic diagram of a transistor according to a fifth embodiment of the present disclosure.

FIG. 10 is a cross-sectional schematic diagram of a transistor according to a sixth embodiment of the present disclosure.

FIG. 11 is a cross-sectional schematic diagram of a transistor according to a seventh embodiment of the present disclosure.

FIG. 12 is a cross-sectional schematic diagram of a transistor according to an eighth embodiment of the present disclosure.

FIG. 13 is a cross-sectional schematic diagram of a transistor according to a ninth embodiment of the present disclosure.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a portion of the element or structure, and certain components in various drawings may not be drawn to scale. In addition, the number and dimension of each component shown in drawings are only illustrative and are not intended to limit the scope of the present disclosure.

Certain terms are used throughout the description and following claims to refer to particular components. As one skilled in the art will understand, electronic equipment manufacturers may refer to a component by different names. This document does not intend to distinguish between components that differ in name but not function. In the following description and in the claims, the terms “include”, “comprise” and “have” are used in an open-ended fashion, and thus should be interpreted to mean “include, but not limited to . . . “. When the terms “include”, “comprise” and/or “have” are used in the description of the present disclosure, the corresponding features, areas, steps, operations and/or components would be pointed to existence, but not limited to the existence or addition of one or a plurality of the corresponding or other features, areas, steps, operations, components and/or combinations thereof.

When an element or layer is referred to as being “on” or “connected to” another element or layer, it may be directly on or directly connected to the other element or layer, or intervening elements or layers may be presented (indirect condition). In contrast, when an element is referred to as being “directly on” or “directly connected to” another element or layer, there are no intervening elements or layers presented.

The directional terms mentioned in this document, such as “up”, “down”, “front”, “back”, “left”, “right”, etc., are only directions referring to the drawings. Therefore, the directional terms used are for illustration, not for limitation of the present disclosure.

The terms “about”, “equal”, “identical” or “the same”, and “substantially” or “approximately” generally mean being within 20% of a given value or range, or being within 10%, 5%, 3%, 2%, 1% or 0.5% of a given value or range.

The ordinal numbers used in the description and claims, such as “first”, “second”, “third”, etc., are used to describe elements, but they do not mean and represent that the element(s) have any previous ordinal numbers, nor do they represent the order of one element and another element, or the order of manufacturing methods. The ordinal numbers are used only to clearly discriminate an element with a certain name from another element with the same name. The claims and the description may not use the same terms. Accordingly, in the following description, a first constituent element may be a second constituent element in a claim.

In the present disclosure, the thickness, length or width and/or the distance between elements may be measured by an optical microscope (OM), a scanning electron microscope (SEM) or other suitable means. For example, the scanning electron microscope may be used to obtain an image of the cross-sectional structure including to-be-measured elements, and the thickness, length or width of each element and/or the distance between elements are measured, but not limited herein.

In the present disclosure, the impedance of the semiconductor may be measured by a spreading resistance profiler (SRP) when the transistor is turned off, or may be measured by a transmission line method (TLM), but not limited herein.

It should be noted that the technical features in different embodiments described in the following can be replaced, recombined, or mixed with one another to constitute another embodiment without departing from the spirit of the present disclosure.

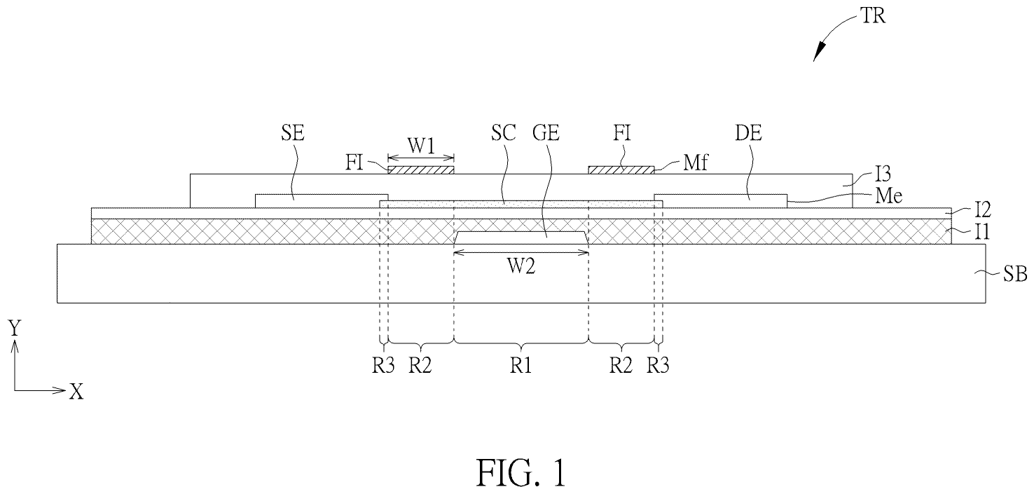

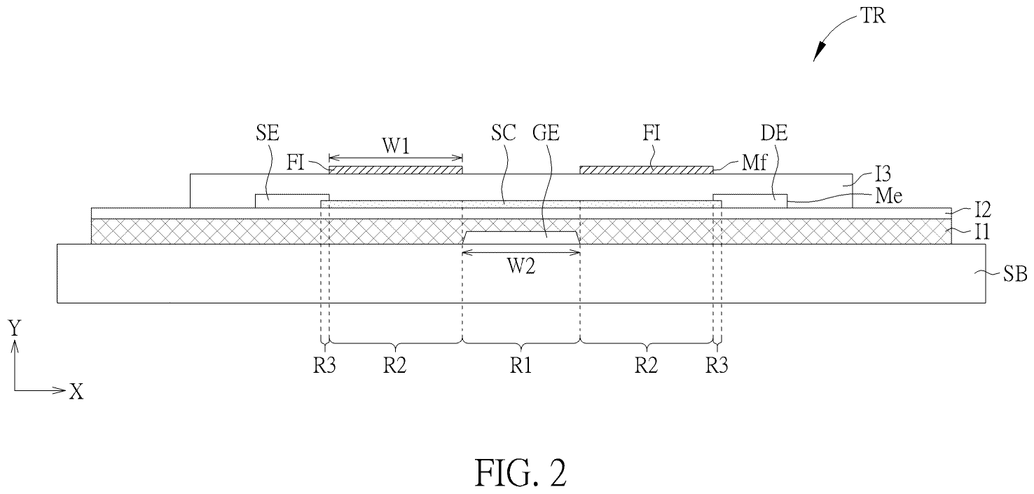

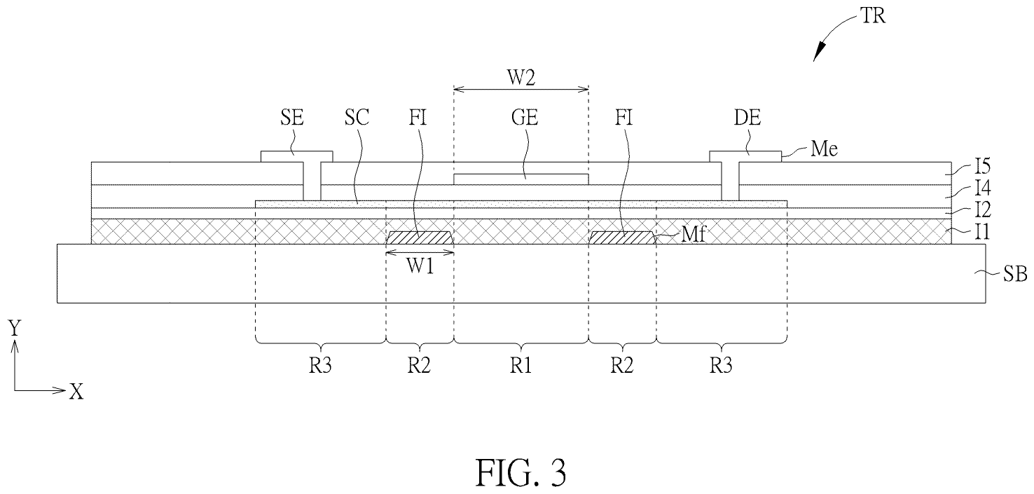

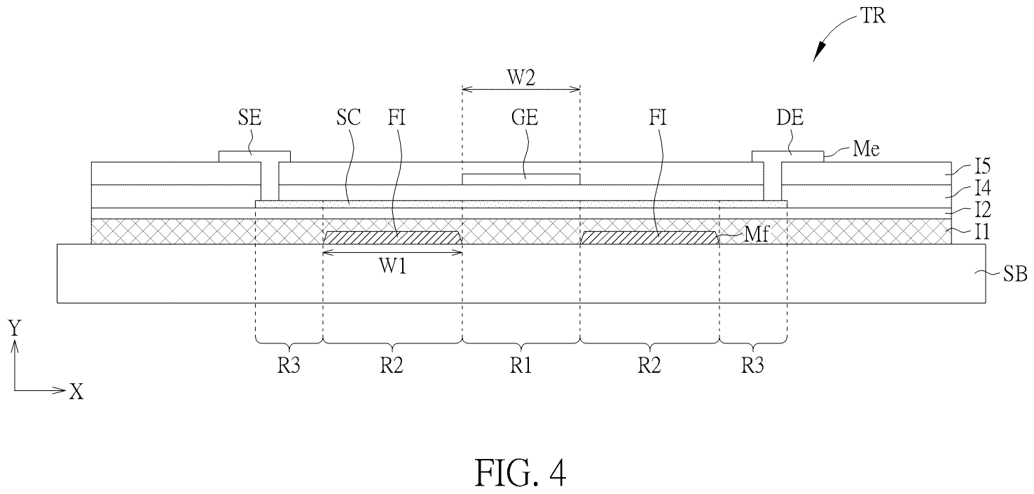

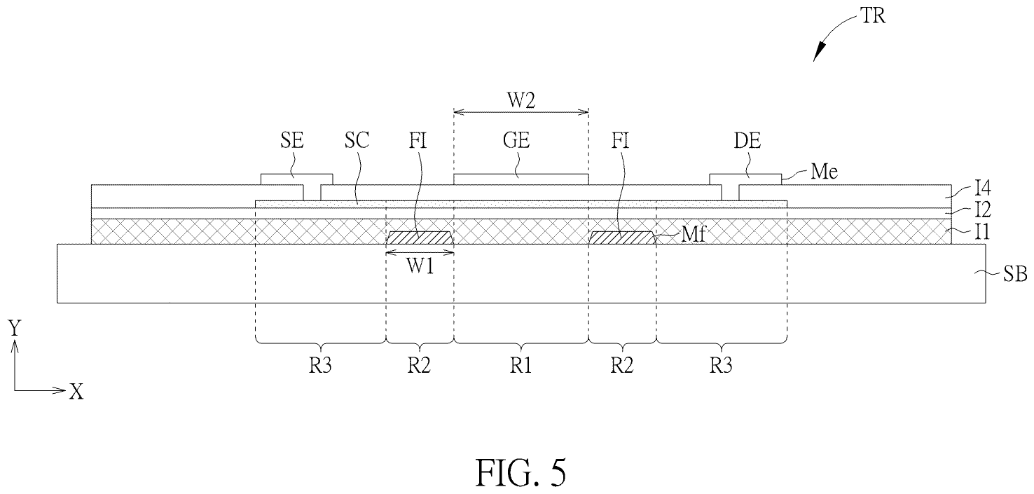

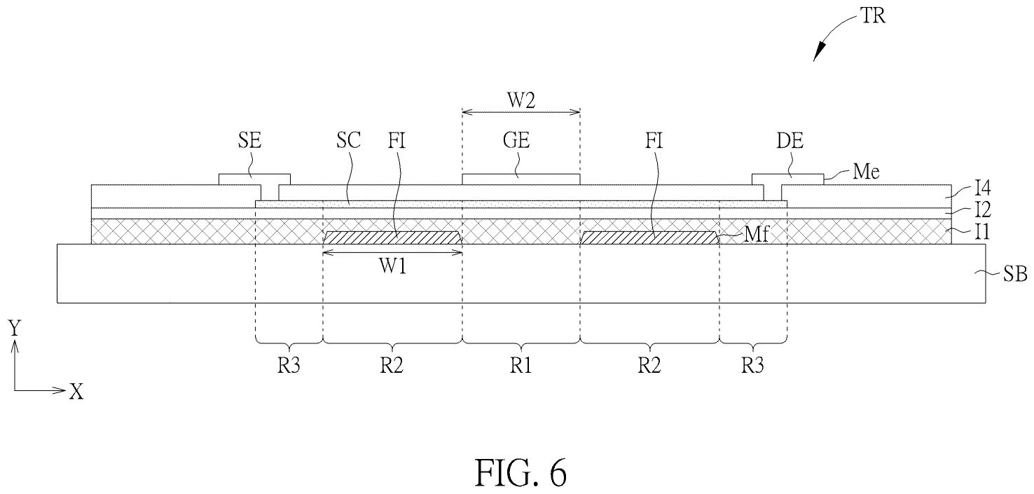

Please refer to FIG. 1, which is a cross-sectional schematic diagram of a transistor according to a first embodiment of the present disclosure. As shown in FIG. 1, a transistor TR includes a substrate SB, an oxide semiconductor layer SC, a gate metal pattern GE, a source metal pattern SE and/or a drain metal pattern DE, and a field induced metal patter FI. The transistor TR may be a bottom-gate transistor (as shown in FIG. 1 and FIG. 2) or a top-gate transistor (as shown in FIG. 3, FIG. 4, FIG. 5 and FIG. 6). The transistor TR is, for example, a thin film transistor (TFT), which may be used in an electronic device such as a display device, a virtual reality device, an augmented reality device or a non-display device (e.g., a package structure or an antenna), so as to serve as a switching element or a driving element, but not limited herein. The substrate SB may include hard material or flexible material, such as including glass, quartz, sapphire, ceramics, polyimide (PI), polycarbonate (PC), polyethylene terephthalate (PET), other suitable material or combinations of the above materials, but not limited herein. The oxide semiconductor layer SC is disposed on the substrate SB and includes a first region R1, a second region R2 and a third region R3, and the second region R2 is disposed between the first region R1 and the third region R3. The material of the oxide semiconductor layer SC may include, for example, indium gallium zinc oxide (IGZO), amorphous indium gallium zinc oxide (a-IGZO), indium zinc oxide (IZO), amorphous indium-zinc-tin oxide (a-IZTO), zinc tin oxide, indium gallium oxide (IGO) or indium gallium zinc tin oxide (IGZTO), but not limited herein. When the transistor TR is turned off, an impedance of the first region R1 is greater than an impedance of the second region R2, and the impedance of the second region R2 is greater than an impedance of the third region R3. The description “transistor is turned off” referred in the present disclosure may indicate a condition that the transistor TR is not conducted or no voltage is applied to the gate metal pattern GE of the transistor TR. Regarding the term “impedance” referred in the present disclosure, the impedance value of the oxide semiconductor layer SC may be measured by a spreading resistance profiler (SRP) when the transistor TR is turned off, or the impedance value may be measured by a transmission line method (TLM), but not limited herein.

According to the embodiment shown in FIG. 1, the gate metal pattern GE is disposed on the substrate SB and overlapped with the first region R1 in a direction Y. The gate metal pattern GE may be located above or below the oxide semiconductor layer SC, wherein in FIG. 1, the gate metal pattern GE is located below the oxide semiconductor layer SC as an example. The source metal pattern SE and the drain metal pattern DE are respectively disposed on at least a portion of the oxide semiconductor layer SC, such as (but not limited to) disposed at two ends of the upper side of the oxide semiconductor layer SC, and the source metal pattern SE or the drain metal pattern DE is overlapped with the third region R3 in the direction Y. The direction Y may be a normal direction of the substrate SB, i.e., the direction Y may be perpendicular to the upper surface or the lower surface of the substrate SB. Specifically, an insulating layer (e.g., an insulating layer I1 and an insulating layer I2 shown in FIG. 1) may exist between the gate metal pattern GE and the oxide semiconductor layer SC, and the first region R1 of the oxide semiconductor layer SC overlapped with the gate metal pattern GE may serve as a channel region of the transistor TR. The source metal pattern SE and the drain metal pattern DE may be respectively overlapped and electrically connected to the third regions R3 at two opposite ends of the oxide semiconductor layer SC. That is to say, one of the source metal pattern SE and the drain metal pattern DE may be overlapped and electrically connected to the third region R3 located at one end of the oxide semiconductor layer SC, and the other of the source metal pattern SE and the drain metal pattern DE may be overlapped and electrically connected to the third region R3 located at the other end of the oxide semiconductor layer SC. In some embodiments, the source metal pattern SE and the drain metal pattern DE may be formed of the same conductive layer Me disposed on the substrate SB, but not limited herein.

The field induced metal pattern FI is disposed on the substrate SB, and in the direction Y, the field induced metal pattern FI is overlapped with the second region R2 and not overlapped with the first region R1 and the third region R3. The field induced metal pattern FI is electrically isolated from the oxide semiconductor layer SC by an insulating layer I3, i.e., the field induced metal pattern FI is not electrically connected to the oxide semiconductor layer SC, and the field induced metal pattern FI may receive a voltage to adjust the impedance of the second region R2 of the oxide semiconductor layer SC when the transistor TR is turned on. The description “transistor is turned on” referred in the present disclosure may indicate a condition that the transistor TR is conducted or a voltage is applied to the gate metal pattern GE of the transistor TR. Specifically, at least one insulating layer (e.g. the insulating layer I3 shown in FIG. 1) exists between the field induced metal pattern FI and the oxide semiconductor layer SC. A turning-on voltage is applied to the gate metal pattern GE when the transistor TR is turned on, and at the same time another voltage signal is also provided to the field induced metal pattern FI. At this time, a capacitance may be formed between the field induced metal pattern FI and the oxide semiconductor layer SC, and thus the impedance of the second region R2 of the oxide semiconductor layer SC overlapped with the field induced metal pattern FI may be adjusted, such that the impedance of the second region R2 may be increased. It should be noted that the voltage value applied to the gate metal pattern GE is different from that provided to the field induced metal pattern FI. For example, the voltage value applied to the gate metal pattern GE may be 20% larger or 20% smaller than the voltage provided to the field induced metal pattern FI. According to the above, when the transistor TR is turned on, the impedance of the second region R2 may be greater than or equal to the impedance of the first region R1, and the impedance of the first region R1 is greater than the impedance of the third region R3. In addition, when the transistor TR is turned on, a voltage difference is generated between the end of the oxide semiconductor layer SC contacting the source metal pattern SE and the end of the oxide semiconductor layer SC contacting the drain metal pattern DE, so that the oxide semiconductor layer SC bears a voltage. By adjusting and increasing the impedance of the second region R2 of the oxide semiconductor layer SC, the voltage that the oxide semiconductor layer SC bears may be dispersed, i.e., the second region R2 is capable of providing the function of voltage dispersion (i.e., dispersing voltage), thereby improving the withstand voltage performance of the transistor TR. That is to say, the oxide semiconductor layer SC may have a first region R1, a second region R2 and a third region R3 with different impedances, which may be regarded as a plurality of resistors connected in series, so different voltage differences may be dispersed in different regions of the oxide semiconductor layer SC. In this embodiment, when one field induced metal pattern FI is provided with a voltage signal (potential), an induced charge (e.g., a negative charge) is generated on the surface of the insulating layer I3 near the field induced metal pattern FI, while an opposite induced charge (e.g., a positive charge) is generated on the surface of the insulating layer I3 far away from the field induced metal pattern FI, so that an electric field is induced on the two surfaces of the insulating layer I3, causing the conductivity of surface carriers of the oxide semiconductor layer SC to change. Furthermore, E (electric field)=V (potential)/R (radius), wherein the electric field is directly proportional to the potential under the condition of fixed radius, and the electric field can be changed by changing the potential. In this embodiment, a capacitance is formed between the field induced metal pattern FI and the oxide semiconductor layer SC when the field induced metal pattern FI is provided with a voltage signal to generate induced charges, and Q (charge amount)=C (capacitance)*V (potential), wherein the potential is inversely proportional to the capacitance, i.e., when the potential changes, the electric field also changes. From the above, the electric field is inversely proportional to the capacitance when the potential (V), the radius (thickness of the insulating layer I3) and the charge amount (induced charge amount of the insulating layer under a potential) are fixed, so the electric field can be inferred from the capacitance, and vice versa, i.e., the capacitance can be inferred from the electric field.

The field induced metal pattern FI may be formed of a conductive layer Mf disposed on the substrate SB. For example, the conductive layer Mf may form two field induced metal patterns FI respectively overlapped with the second regions R2 located at two opposite sides of the first region R1 and not overlapped with the first region R1. In some embodiments, in a direction X (e.g., a direction perpendicular to the extension direction of a gate line in a top-view of the transistor), a width W1 of each field induced metal pattern FI may be less than or equal to a width W2 of the gate metal pattern GE, wherein the direction X may be perpendicular to the direction Y, for example. The term “width” referred in the present disclosure may indicate a length measured from one end to another end of the layer or element along the direction X in a cross-sectional view. In some embodiments, the second region R2 of the oxide semiconductor layer SC may be an additional ion doped region, for example, a lightly doped region, i.e., an additional ion implantation may be performed at a predetermined position of the second region R2 of the oxide semiconductor layer SC in the manufacturing process for doping elements, such as boron, argon, chlorine, fluorine, neon, hydrogen or other suitable elements, but the present disclosure is not limited to the above. The second region R2 of the oxide semiconductor layer SC may not be additionally doped with other elements in other embodiments. Further, the ion doping concentration in the oxide semiconductor layer SC is that the ion doping concentration of the third region R3 is greater than or equal to that of the second region R2, and the ion doping concentration of the second region R2 is greater than that of the first region R1.

According to the embodiment shown in FIG. 1, the transistor TR may be a bottom-gate transistor, and the transistor TR may include, for example, the gate metal pattern GE, the insulating layer I1, the insulating layer I2, the oxide semiconductor layer SC, the conductive layer Me forming the source metal pattern SE and the drain metal pattern DE, the insulating layer I3 and the conductive layer Mf forming the field induced metal pattern FI, which are disposed on the substrate SB along the direction Y in sequence. The materials of the gate metal pattern GE, the conductive layer Me and the conductive layer Mf may include, for example (but not limited to), metal materials such as titanium, copper, aluminum, tin, nickel, gold or silver or other suitable conductive materials. In other embodiments, the material of one or both of the source metal pattern SE and the drain metal pattern DE may include indium tin oxide (ITO), but not limited herein. In some embodiments, the field induced metal pattern FI may include, for example (but not limited to), a transparent conductive material such as indium tin oxide. The materials of the insulating layer I1 and the insulating layer I2 may include, for example (but not limited to), silicon nitride (SiNx), silicon oxide (SiOx), silicon oxynitride (SiNxOy), polyimide (PI), polyester or combinations of the above materials, wherein the insulating layer I1 and the insulating layer I2 may serve as buffer layers. The material of the insulating layer I3 may include, for example (but not limited to), an organic insulating material, such as poly(methyl methacrylate) (PMMA), epoxy, acrylic-based resin, silicone or polyimide polymer, wherein the insulating layer I3 may serve as a protective layer. In addition, the insulating layer I1 and the insulating layer I2 may be made of the same material or different materials, and the thickness of the insulating layer I1 may be the same as or different from that of the insulating layer I2.

In other embodiments, the field induced metal pattern FI and the gate metal pattern GE may be located at the same layer (not shown), i.e., the field induced metal pattern FI and the gate metal pattern GE may be, for example, formed of the same conductive layer disposed on the upper surface of the substrate SB, wherein the field induced metal pattern FI and the gate metal pattern GE may be separated from each other by 0.5 micrometers (μm) to 5 micrometers in the direction X, so that the probability of short circuit may be reduced. The terminology “separated from” refers to the minimum distance between the field induced metal pattern FI and the gate metal pattern GE, i.e., measured from a side of the field induced metal pattern FI facing the gate metal pattern GE to a side of the gate metal pattern GE facing the field induced metal pattern FI in a cross-sectional view in the direction X (e.g., a direction perpendicular to the extension direction of a gate line in a top-view of the transistor).

Please refer to FIG. 2, which is a cross-sectional schematic diagram of a transistor according to a variant embodiment of a first embodiment of the present disclosure. According to the transistor TR shown in FIG. 2, in a cross-sectional view in the direction X (e.g., a direction perpendicular to the extension direction of a gate line in a top-view of the transistor), the width W1 of the field induced metal pattern FI may be greater than or equal to the width W2 of the gate metal pattern GE. For example, a ratio of the width W1 of the field induced metal pattern FI to the width W2 of the gate metal pattern GE may be greater than or equal to 1 and less than or equal to 2 (i.e., 1≤W1/W2≤2), but not limited herein. In some embodiments, the sum of the widths of the two field induced metal patterns FI may be greater than or equal to twice the width W2 of the gate metal pattern GE, i.e., in the direction X, the sum of the widths of the second regions R2 of the oxide semiconductor layer SC overlapped with the field induced metal patterns FI may be greater than or equal to twice the width of the first region R1 of the oxide semiconductor layer SC overlapped with the gate metal pattern GE. Through the design of increasing the width of the field induced metal pattern FI (or the second region R2), the impedance of the second region R2 of the oxide semiconductor layer SC may be increased, thereby improving the voltage dispersion effect of the second region R2.

Please refer to FIG. 3, which is a cross-sectional schematic diagram of a transistor according to a second embodiment of the present disclosure. As show in FIG. 3, the transistor TR may be a top-gate transistor, and the transistor TR may include, for example, the conductive layer Mf forming the field induced metal pattern FI, the insulating layer I1, the insulating layer I2, the oxide semiconductor layer SC, an insulating layer I4, the gate metal pattern GE, an insulating layer I5 and the conductive layer Me forming the source metal pattern SE and the drain metal pattern DE, which are disposed on the substrate SB along the direction Y in sequence. The field induced metal pattern FI is overlapped with the second region R2 of the oxide semiconductor layer SC and not overlapped with the first region R1 thereof in the direction Y, and the field induced metal pattern FI may receive a voltage to adjust the impedance of the second region R2 of the oxide semiconductor layer SC. The gate metal pattern GE is overlapped with the first region R1 of the oxide semiconductor layer SC, wherein in the direction X, the width W1 of each field induced metal pattern FI may be less than the width W2 of the gate metal pattern GE. The source metal pattern SE or the drain metal pattern DE is overlapped with the third region R3, and the source metal pattern SE and the drain metal pattern DE may be electrically connected to the third regions R3 at two opposite ends of the oxide semiconductor layer SC through the connection holes in the insulating layer I4 and the insulating layer I5, respectively. The materials of the insulating layer I4 and the insulating layer I5 may include, for example (but not limited to), silicon nitride (SiNx), silicon oxide (SiOx), silicon oxynitride (SiOxNy) or other suitable materials, wherein the insulating layer I4 may serve as a gate dielectric layer, the insulating layer I5 may serve as an interlayer dielectric layer, and the insulating layer I4 and insulating layer I5 may include the same or different materials. The sum of the thicknesses of the insulating layer I4 and the insulating layer I5 may be greater than or equal to the minimum distance between the field induced metal pattern FI and the oxide semiconductor layer SC, and the thickness of the insulating layer I4 may be the same as or different from that of the insulating layer I5. The above contents regarding the materials and thicknesses of the insulating layer I4 and the insulating layer I5 may further be applied to the insulating layer I4 and the insulating layer I5 in other embodiments of the present disclosure. The materials of other elements and layers of the transistor TR shown in FIG. 3 may refer to the related contents of the embodiment shown in FIG. 1 described above, which will not be described redundantly herein.

In some embodiments, the field induced metal pattern FI and the gate metal pattern GE may be located at the same layer (not shown), i.e., the field induced metal pattern FI and the gate metal pattern GE may be, for example, formed of the same conductive layer disposed on the insulating layer I4, wherein the field induced metal pattern FI and the gate metal pattern GE may be separated from each other by 0.5 micrometers (μm) to 5 micrometers in the direction X, so that the probability of short circuit may be reduced. The terminology “separated from” refers to the minimum distance between the field induced metal pattern FI and the gate metal pattern GE, i.e., measured from a side of the field induced metal pattern FI facing the gate metal pattern GE to a side of the gate metal pattern GE facing the field induced metal pattern FI in a cross-sectional view in the direction X (e.g., a direction perpendicular to the extension direction of a gate line in a top-view of the transistor).

Please refer to FIG. 4, which is a cross-sectional schematic diagram of a transistor according to a variant embodiment of a second embodiment of the present disclosure. According to the transistor TR shown in FIG. 4, in the direction X, the width W1 of the field induced metal pattern FI may be greater than or equal to the width W2 of the gate metal pattern GE. The width design of the field induced metal pattern FI shown in FIG. 4 may refer to the related contents of the embodiment shown in FIG. 2 described above, which will not be described redundantly herein. Through increasing the width of the field induced metal pattern FI (or the second region R2), the voltage dispersion effect of the second region R2 may be improved.

Please refer to FIG. 5, which is a cross-sectional schematic diagram of a transistor according to a third embodiment of the present disclosure. As shown in FIG. 5, the transistor TR may be a top-gate transistor, and the transistor TR may include, for example, the conductive layer Mf forming the field induced metal pattern FI, the insulating layer I1, the insulating layer I2, the oxide semiconductor layer SC, the insulating layer I4 and the conductive layer Me, which are disposed on the substrate SB along the direction Y in sequence. The conductive layer Me forms the gate metal pattern GE, the source metal pattern SE and the drain metal pattern DE, i.e., the gate metal pattern GE, the source metal pattern SE and the drain metal pattern DE may be formed by the same conductive layer Me. That is to say, the gate metal pattern GE, the source metal pattern SE and the drain metal pattern DE may be manufactured by the same process, so that the process steps may be reduced and the cost is saved. According to the embodiment shown in FIG. 5, in the direction X, the width W1 of each field induced metal pattern FI may be less than the width W2 of the gate metal pattern GE. The relative arrangement positions and materials of other elements and layers of the transistor TR shown in FIG. 5 may refer to the related contents of the embodiment shown in FIG. 3 described above, which will not be described redundantly herein.

Please refer to FIG. 6, which is a cross-sectional schematic diagram of a transistor according to a variant embodiment of a third embodiment of the present disclosure. According to the transistor TR shown in FIG. 6, in the direction X, the width W1 of the field induced metal pattern FI may be greater than or equal to the width W2 of the gate metal pattern GE. Through increasing the width of the field induced metal pattern FI (or the second region R2), the impedance of the second region R2 of the oxide semiconductor layer SC may be increased, thereby improving the voltage dispersion effect of the second region R2.

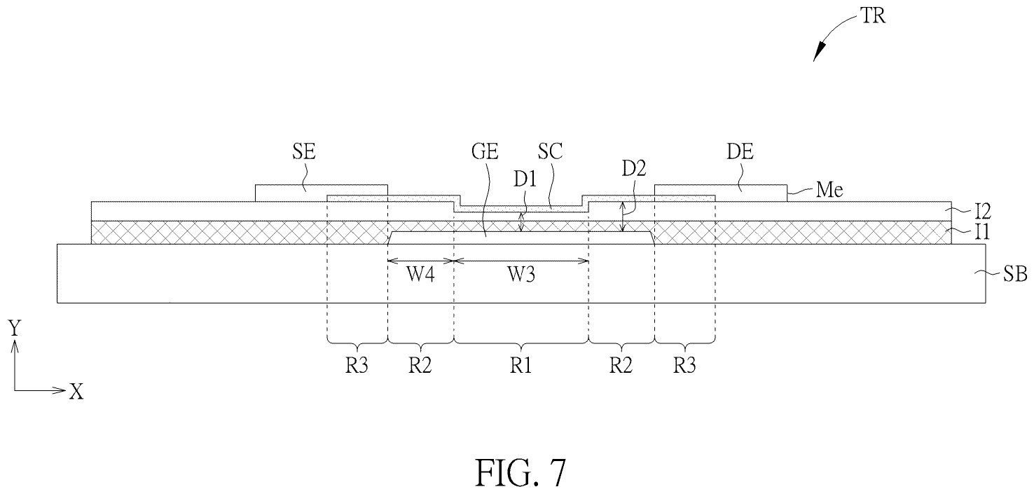

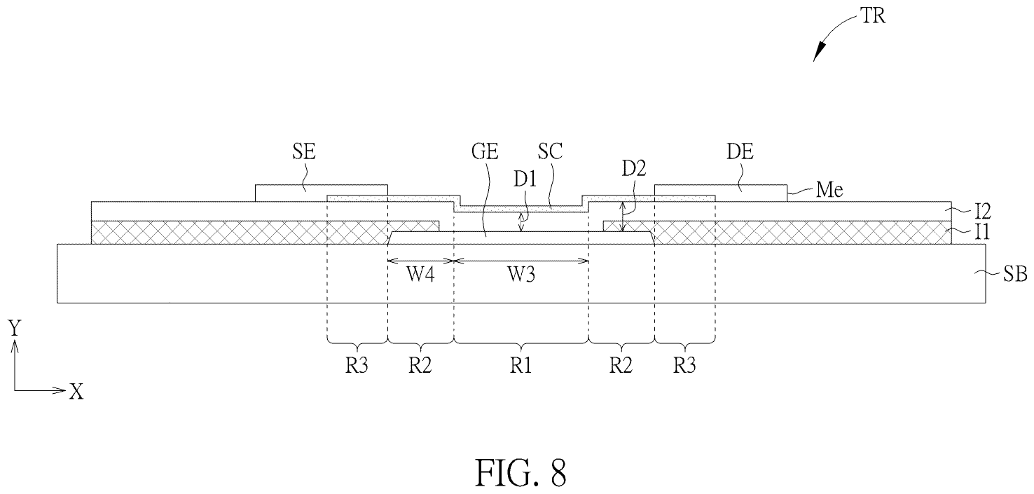

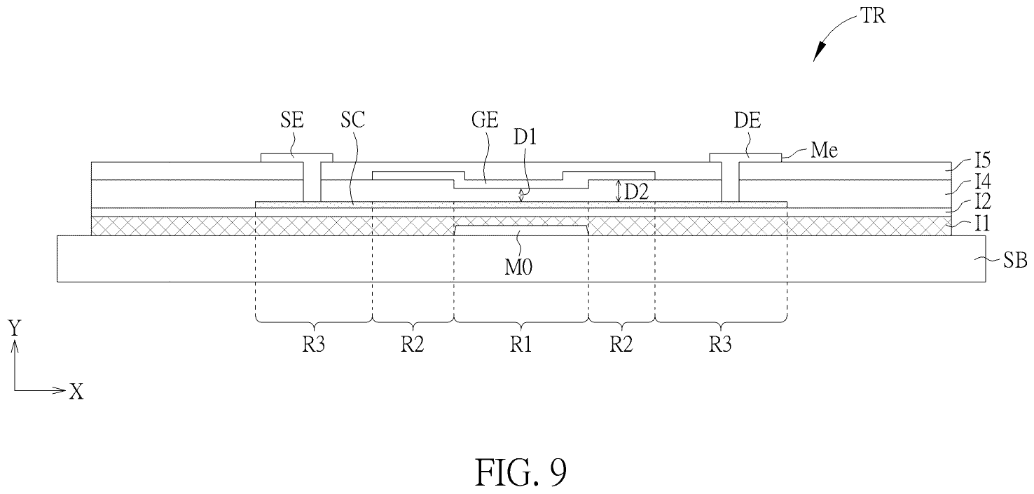

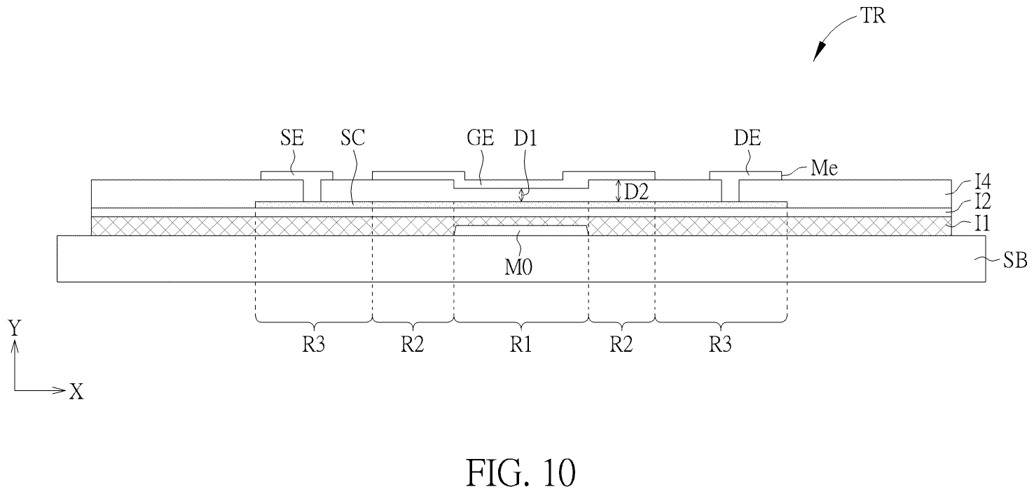

Please refer to FIG. 7, which is a cross-sectional schematic diagram of a transistor according to a fourth embodiment of the present disclosure. As shown in FIG. 7, a transistor TR includes a substrate SB, an oxide semiconductor layer SC, a gate metal pattern GE, and a source metal pattern SE/drain metal pattern DE. The transistor TR may be a bottom-gate transistor (as shown in FIG. 7 and FIG. 8) or a top-gate transistor (as shown in FIG. 9 and FIG. 10). The oxide semiconductor layer SC is disposed on the substrate SB and includes a first region R1, a second region R2 and a third region R3, and the second region R2 is disposed between the first region R1 and the third region R3. When the transistor TR is turned off, an impedance of the first region R1 is greater than an impedance of the second region R2, and the impedance of the second region R2 is greater than an impedance of the third region R3. The gate metal pattern GE is disposed on the substrate SB and overlapped with the first region R1 and the second region R2 is the direction Y. The source metal pattern SE and the drain metal pattern DE are respectively disposed on the oxide semiconductor layer SC, and the source metal pattern SE or the drain metal pattern DE is overlapped with the third region R3 in the direction Y. Specifically, an insulating layer (e.g., an insulating layer I1 and an insulating layer I2 shown in FIG. 7) may exist between the gate metal pattern GE and the oxide semiconductor layer SC, and the first region R1 of the oxide semiconductor layer SC overlapped with the gate metal pattern GE may serve as a channel region of the transistor TR. The source metal pattern SE and the drain metal pattern DE may be respectively overlapped and electrically connected to the third regions R3 at two opposite ends of the oxide semiconductor layer SC. In some embodiments, the source metal pattern SE and the drain metal pattern DE may be formed of the same conductive layer Me disposed on the substrate SB, but not limited herein.

In the direction Y, a minimum distance between the first region R1 of the oxide semiconductor layer SC and the gate metal pattern GE is defined as a first distance D1, a minimum distance between the second region R2 of the oxide semiconductor layer SC and the gate metal pattern GE is defined as a second distance D2, and the first distance D1 is less than the second distance D2. The first distance D1 may be greater than or equal to 500 angstroms (Å) and less than or equal to 3000 angstroms, the second distance D2 may be greater than 500 angstroms and less than or equal to 5000 angstroms, and a ratio of the first distance D1 to the second distance D2 is greater than or equal to 0.1 and less than 1 (i.e., 0.1≤D1/D2<1).

Specifically, according to the embodiment shown in FIG. 7, the transistor TR may be a bottom-gate transistor, and the transistor TR may include, for example, the gate metal pattern GE, the insulating layer I1, the insulating layer I2, the oxide semiconductor layer SC and the conductive layer Me forming the source metal pattern SE and the drain metal pattern DE, which are disposed on the substrate SB along the direction Y in sequence. In the direction Y, the thickness of a portion of the insulating layer I2 corresponding to (or overlapped with) the first region R1 may be less than the thickness of another portion of the insulating layer I2 corresponding to (or overlapped with) the second region R2, so that the minimum distance between the lower surface of the first region R1 of the oxide semiconductor layer SC and the upper surface of the gate metal pattern GE in the direction Y (i.e., the first distance D1) is less than the minimum distance between the lower surface of the second region R2 of the oxide semiconductor layer SC and the upper surface of the gate metal pattern GE in the direction Y (i.e., the second distance D2). For example, in the manufacturing process of the transistor TR, an etching process may be performed on the insulating layer I2 after the insulating layer I2 is formed on the insulating layer I1, so as to form a step difference occurring between the portion of the insulating layer I2 corresponding to the first region R1 and the another portion of the insulating layer I2 corresponding to the second region R2, and then the next processes are performed on the insulating layer I2, such that a layer thickness difference between the second distance D2 and the first distance D1 shown in FIG. 7 is formed.

When the transistor TR is turned on, a voltage difference is generated between one end of the oxide semiconductor layer SC contacting the source metal pattern SE and another end of the oxide semiconductor layer SC contacting the drain metal pattern DE, so that the oxide semiconductor layer SC bears a voltage. Furthermore, due to the smaller first distance D1, a larger capacitance may be formed between the first region R1 of the oxide semiconductor layer SC and the gate metal pattern GE, and the first region R1 of the oxide semiconductor layer SC has a lower impedance, while due to the larger second distance D2, a smaller capacitance may be formed between the second region R2 of the oxide semiconductor layer SC and the gate metal pattern GE, and the second region R2 of the oxide semiconductor layer SC has a higher impedance, so that the voltage on the oxide semiconductor layer SC may be dispersed to achieve the function of voltage dispersion. According to the above structural design that the first distance D1 is less than the second distance D2, when the transistor TR is turned on, the impedance of the second region R2 may be greater than or equal to the impedance of the first region R1, and the impedance of the first region R1 is greater than the impedance of the third region R3. By adjusting and increasing the impedance of the second region R2 of the oxide semiconductor layer SC, the voltage that the oxide semiconductor layer SC bears may be dispersed, i.e., the second region R2 is capable of providing the function of voltage dispersion, thereby improving the withstand voltage performance of the transistor TR.

In some embodiments, in the direction X, a width W3 of the first region R1 may be greater than or equal to a width W4 of the second region R2, but not limited herein. In some embodiments, the second region R2 of the oxide semiconductor layer SC may further be ion-implanted to include other doping elements, thereby forming a low-concentration doped region, but the present disclosure is not limited thereto. The second region R2 of the oxide semiconductor layer SC may not be doped with other elements in other embodiments.

Please refer to FIG. 8, which is a cross-sectional schematic diagram of a transistor according to a variant embodiment of a fourth embodiment of the present disclosure. According to the transistor TR shown in FIG. 8, in the direction Y, the thickness of a portion of the insulating layer I1 corresponding to the first region R1 may be less than the thickness of another portion of the insulating layer I1 corresponding to the second region R2, so that the first distance D1 between the lower surface of the first region R1 of the oxide semiconductor layer SC and the upper surface of the gate metal pattern GE is less than the second distance D2 between the lower surface of the second region R2 of the oxide semiconductor layer SC and the upper surface of the gate metal pattern GE. Therefore, the second region R2 may achieve the function of voltage dispersion. For example, in the manufacturing process of the transistor TR, an etching process may be performed on the insulating layer I1 after the insulating layer I1 is formed on the substrate SB and the gate metal pattern GE, so as to form a step difference occurring between the portion of the insulating layer I1 corresponding to the first region R1 and the another portion of the insulating layer I1 corresponding to the second region R2, and then the next processes are performed on the insulating layer I1, such that a layer thickness difference between the second distance D2 and the first distance D1 shown in FIG. 8 is formed. In another embodiment, a portion of the insulating layer I1 may be removed by the etching process to expose a portion of the gate metal pattern GE below, and then the insulating layer I2 is formed on the insulating layer I1 and the exposed portion of the gate metal pattern GE, but not limited herein.

Please refer to FIG. 9, which is a cross-sectional schematic diagram of a transistor according to a fifth embodiment of the present disclosure. As shown in FIG. 9, the transistor TR may be a top-gate transistor, and the transistor TR may include, for example, the insulating layer I1, the insulating layer I2, the oxide semiconductor layer SC, an insulating layer I4, the gate metal pattern GE, an insulating layer I5 and the conductive layer Me forming the source metal pattern SE and the drain metal pattern DE, which are disposed on the substrate SB along the direction Y in sequence. The gate metal pattern GE is overlapped with the first region R1 and the second region R2 of the oxide semiconductor layer SC in the direction Y. The source metal pattern SE or the drain metal pattern DE is overlapped with the third region R3, and the source metal pattern SE and the drain metal pattern DE may be electrically connected to the third regions R3 at two opposite ends of the oxide semiconductor layer SC through the connection holes in the insulating layer I4 and the insulating layer I5, respectively.

In the direction Y, the thickness of a portion of the insulating layer I4 corresponding to the first region R1 may be less than the thickness of another portion of the insulating layer I4 corresponding to the second region R2, so that the minimum distance between the upper surface of the first region R1 of the oxide semiconductor layer SC and the lower surface of the gate metal pattern GE in the direction Y (i.e., the first distance D1) is less than the minimum distance between the upper surface of the second region R2 of the oxide semiconductor layer SC and the lower surface of the gate metal pattern GE in the direction Y (i.e., the second distance D2). Therefore, the second region R2 may achieve the function of voltage dispersion. For example, in the manufacturing process of the transistor TR, an etching process may be performed on the insulating layer I4 after the insulating layer I4 is formed on the oxide semiconductor layer SC, so as to form a step difference occurring between the portion of the insulating layer I4 corresponding to the first region R1 and the another portion of the insulating layer I4 corresponding to the second region R2,

According to the embodiment shown in FIG. 9, the transistor TR may further include a conductive layer M0 disposed between the substrate SB and the insulating layer I1. In some embodiments, the conductive layer M0 may serve as a light shielding layer, and the pattern of the conductive layer M0 may correspond to at least a portion of the gate metal pattern GE. For example, the conductive layer M0 may be overlapped with the first region R1 of the oxide semiconductor layer SC and a portion of the gate metal pattern GE in the direction Y. As a light shielding layer, the conductive layer M0 may include, for example (but not limited to), a metal material, a black photoresist material or other materials with better light absorption. In some embodiments, the conductive layer M0 may serve as another gate, and the conductive layer M0 and the gate metal pattern GE may receive the same signal and have the same potential. For example, the conductive layer M0 may be electrically connected to the gate metal pattern GE in the peripheral area to form a double gate structure, but not limited herein. In other embodiments, the conductive layer M0 may serve as a field induced metal pattern, and the conductive layer M0 and the gate metal pattern GE may receive different signals respectively, so that the conductive layer M0 is capable of receiving a voltage to adjust the impedance of the first region R1 of the oxide semiconductor layer SC.

Please refer to FIG. 10, which is a cross-sectional schematic diagram of a transistor according to a sixth embodiment of the present disclosure. As shown in FIG. 10, the transistor TR may be a top-gate transistor, and the transistor TR may include, for example, the conductive layer M0, the insulating layer I1, the insulating layer I2, the oxide semiconductor layer SC, the insulating layer I4 and the conductive layer Me, which are disposed on the substrate SB along the direction Y in sequence. The conductive layer Me forms the gate metal pattern GE, the source metal pattern SE and the drain metal pattern DE, i.e., the gate metal pattern GE, the source metal pattern SE and the drain metal pattern DE may be formed by the same conductive layer Me. That is to say, the gate metal pattern GE, the source metal pattern SE and the drain metal pattern DE may be made of the same material in this embodiment, i.e., they may be manufactured by the same process, so that the process steps may be reduced and the cost is saved. The relative arrangement positions and materials of other elements and layers of the transistor TR shown in FIG. 10 may refer to the related contents of the embodiment shown in FIG. 9 described above, which will not be described redundantly herein.

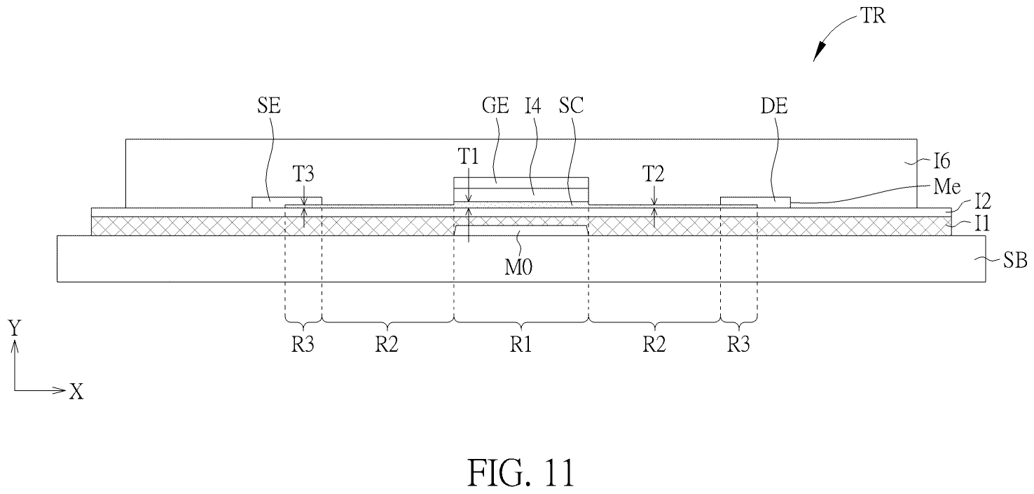

Please refer to FIG. 11, which is a cross-sectional schematic diagram of a transistor according to a seventh embodiment of the present disclosure. As shown in FIG. 11, a transistor TR includes a substrate SB, an oxide semiconductor layer SC, a gate metal pattern GE, a source metal pattern SE and/or a drain metal pattern DE. The oxide semiconductor layer SC is disposed on the substrate SB and includes a first region R1, a second region R2 and a third region R3, and the second region R2 is disposed between the first region R1 and the third region R3. When the transistor TR is turned off, an impedance of the first region R1 is greater than an impedance of the second region R2, and the impedance of the second region R2 is greater than an impedance of the third region R3. The gate metal pattern GE is disposed on the substrate SB, and the gate metal pattern GE is disposed on the oxide semiconductor layer SC and overlapped with the first region R1 in the direction Y. The source metal pattern SE and the drain metal pattern DE are respectively disposed on the oxide semiconductor layer SC, and the source metal pattern SE or the drain metal pattern DE is overlapped with the third region R3 in the direction Y. Specifically, an insulating layer I4 exists between the gate metal pattern GE and the oxide semiconductor layer SC, and the first region R1 of the oxide semiconductor layer SC overlapped with the gate metal pattern GE may serve as a channel region of the transistor TR. The source metal pattern SE and the drain metal pattern DE may be respectively overlapped and electrically connected to the third regions R3 at two opposite ends of the oxide semiconductor layer SC. In some embodiments, the gate metal pattern GE, the source metal pattern SE and the drain metal pattern DE may be formed of the same conductive layer Me disposed on the substrate SB, but not limited herein.

In the direction Y, the first region R1 of the oxide semiconductor layer SC has a first thickness T1, the second region R2 of the oxide semiconductor layer SC has a second thickness T2, and the first thickness T1 is greater than the second thickness T2. The first thickness T1 may be greater than or equal to 50 angstroms and less than or equal to 500 angstroms, the second thickness T2 may be greater than or equal to 5 angstroms and less than or equal to 50 angstroms, and a ratio of the first thickness T1 to the second thickness T2 is greater than or equal to 1 and less than or equal to 100 (i.e., 1≤T1/T2≤100).

When the transistor TR is turned on, a voltage difference is generated between one end of the oxide semiconductor layer SC contacting the source metal pattern SE and another end of the oxide semiconductor layer SC contacting the drain metal pattern DE, so that the oxide semiconductor layer SC bears a voltage. Furthermore, the first region R1 of the oxide semiconductor layer SC has a lower impedance due to the thicker first thickness T1, while the second region R2 of the oxide semiconductor layer SC has a higher impedance due to the thinner second thickness T2, which may achieve the function of voltage dispersion. According to the above structural design that the first thickness T1 is greater than the second thickness T2, when the transistor TR is turned on, the impedance of the second region R2 may be greater than or equal to the impedance of the first region R1, and the impedance of the first region R1 is greater than the impedance of the third region R3. By adjusting and increasing the impedance of the second region R2 of the oxide semiconductor layer SC, the second region R2 may achieve the function of voltage dispersion, thereby improving the withstand voltage performance of the transistor TR. In some embodiments, in the direction Y, the third region R3 of the oxide semiconductor layer SC may have a third thickness T3, and the third thickness T3 may be greater than or equal to the second thickness T2. For example, the third thickness T3 may be equal to the second thickness T2, but the present disclosure is not limited thereto. The third thickness T3 may be greater than the second thickness T2 and equal to the first thickness T1 in other embodiments.

According to the embodiment shown in FIG. 11, the transistor TR may be a top-gate transistor, and the transistor TR may include, for example, the insulating layer I1, the insulating layer I2, the oxide semiconductor layer SC, an insulating layer I4 and a conductive layer Me, which are disposed on the substrate SB along the direction Y in sequence. The conductive layer Me forms the gate metal pattern GE, the source metal pattern SE and the drain metal pattern DE. In the direction Y, the insulating layer I4 may be disposed between the gate metal pattern GE and the oxide semiconductor layer SC, and the insulating layer I4 may be overlapped with the first region R1 and not overlapped with the second region R2 and the third region R3. That is to say, the insulating layer I4 may cover the first region R1 of the oxide semiconductor layer SC and expose the second region R2 and the third region R3 thereof, so that the source metal pattern SE and the drain metal pattern DE may be directly disposed on the oxide semiconductor layer SC, without requiring connection holes for electrically connection thereto, thereby reducing the space occupied by the connection holes and making the element size smaller.

As shown in FIG. 11, in some embodiments, the transistor TR may further include a conductive layer M0 disposed between the substrate SB and the insulating layer I1, wherein the conductive layer M0 may serve as a light shielding layer, another gate or a field induced metal pattern, and the detailed implements thereof may refer to the related contents of the embodiment shown in FIG. 9 described above, which will not be described redundantly herein. In some embodiments, the transistor TR may further include an insulating layer I6 disposed on the insulating layer I2, the oxide semiconductor layer SC and the conductive layer Me, so as to cover and protect the oxide semiconductor layer SC, the gate metal pattern GE, the source metal pattern SE and the drain metal pattern DE. In some embodiments, the second region R2 of the oxide semiconductor layer SC may further be ion-implanted to include other doping elements, thereby forming a low-concentration doped region, but the present disclosure is not limited thereto. The second region R2 of the oxide semiconductor layer SC may not be doped with other elements in other embodiments.

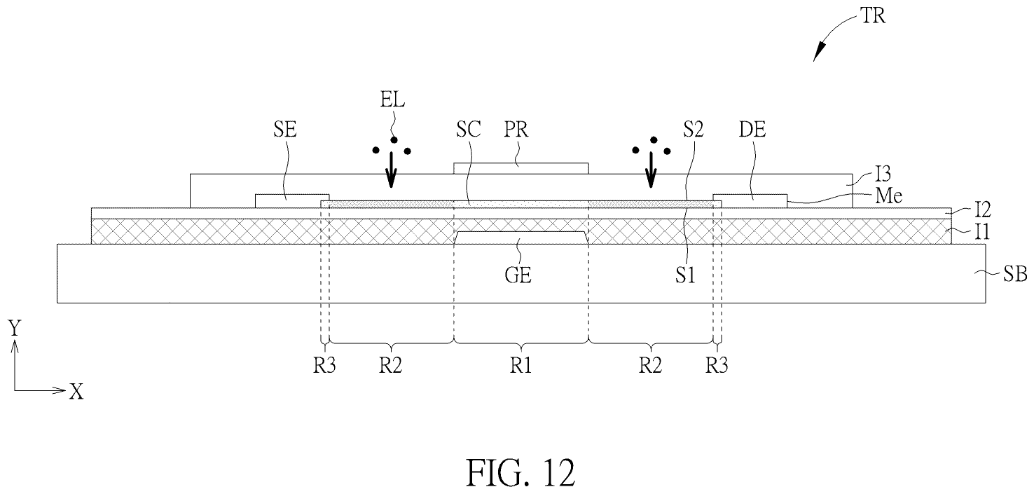

Please refer to FIG. 12, which is a cross-sectional schematic diagram of a transistor according to an eighth embodiment of the present disclosure. As shown in FIG. 12, the transistor TR may be a bottom-gate transistor, and the transistor TR may include, for example, the gate metal pattern GE, the insulating layer I1, the insulating layer I2, the oxide semiconductor layer SC, the conductive layer Me forming the source metal pattern SE and the drain metal pattern DE and the insulating layer I3, which are disposed on the substrate SB along the direction Y in sequence. The detailed structures and materials of the above elements and layers may refer to the related contents of the embodiment shown in FIG. 1 described above, which will not be described redundantly herein. According to the embodiment shown in FIG. 12, the second region R2 of the oxide semiconductor layer SC may be ion-implanted for doping an element EL, such as doping boron, argon, chlorine, fluorine, neon, hydrogen or other suitable elements. For example, in the manufacturing process of the transistor TR, a photoresist pattern PR may be disposed on the insulating layer I3 corresponding to the first region R1 of the oxide semiconductor layer SC, and then ion implantation may be performed to dope the element EL into the second region R2 of the oxide semiconductor layer SC for adjusting the impedance of the second region R2. By adjusting and increasing the impedance of the second region R2 of the oxide semiconductor layer SC, the second region R2 may achieve the function of voltage dispersion, thereby improving the withstand voltage performance of the transistor TR. Furthermore, after the second region R2 of the oxide semiconductor layer SC is ion-implanted for doping the elements, the concentration of the doped elements varies from an upper surface S2 to a lower surface S1 of the oxide semiconductor layer SC. Specifically, the oxide semiconductor layer SC has the lower surface S1 and the upper surface S2 opposite to each other, wherein the lower surface S1 faces the substrate SB, and the upper surface S2 is farther away from the substrate SB than the lower surface S1. In the second region R2, the thickness of the oxide semiconductor layer SC is divided into ten equal parts, and the ion concentration of the doped elements EL may present the following distribution. The doping ion concentration from the upper surface S2 of the oxide semiconductor layer SC to the position at one-tenth of the depth thereof (i.e., the position at nine-tenths of the thickness of the oxide semiconductor layer SC, and the relationship between the depth and the thickness in the following may be analogized accordingly) may be defined as a first ion concentration, and the doping ion concentration from the position at nine-tenths of the depth of the oxide semiconductor layer SC to the lower surface S1 may be defined as a second ion concentration, wherein the first ion concentration may be less than the second ion concentration. In addition, the doping ion concentration from the position at five-tenths of the depth to the position at six-tenths of the depth of the oxide semiconductor layer SC may be less than the above second ion concentration, and the doping ion concentration from the position at seven-tenths of the depth to the position at eight-tenths of the depth of the oxide semiconductor layer SC may be greater than the above first ion concentration. In some embodiments, in the second region R2 of the oxide semiconductor layer SC, a maximum doping ion concentration exists from the position at seven tenths of the depth to the position at eight tenths of the depth, but not limited herein. In some embodiments, the doping ion concentration in the substrate SB may be less than the doping ion concentration of the oxide semiconductor layer SC, but not limited herein.

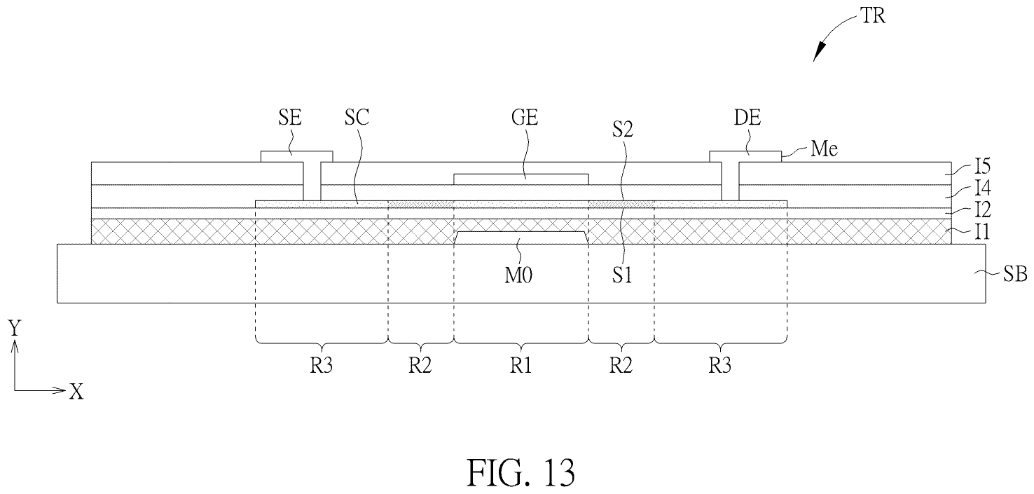

Please refer to FIG. 13, which is a cross-sectional schematic diagram of a transistor according to a ninth embodiment of the present disclosure. As shown in FIG. 13, the transistor TR may be a top-gate transistor, and the transistor TR may include, for example, the conductive layer M0, the insulating layer I1, the insulating layer I2, the oxide semiconductor layer SC, the insulating layer I4, the gate metal pattern GE, the insulating layer I5 and the conductive layer Me forming the source metal pattern SE and the drain metal pattern DE, which are disposed on the substrate SB along the direction Y in sequence. The detailed structures and materials of the above elements and layers may refer to the related contents of the embodiments shown in FIG. 3 and FIG. 9 described above, which will not be described redundantly herein. According to the embodiment shown in FIG. 13, an ion implantation process may be performed on the second region R2 of the oxide semiconductor layer SC to make the second region R2 contain doping elements, such as doping boron, argon, chlorine, fluorine, neon, hydrogen or other suitable elements. For example, in the manufacturing process of the transistor TR, a photoresist pattern (e.g., the photoresist pattern PR shown in FIG. 12) may be disposed on the insulating layer I4 corresponding to the first region R1 of the oxide semiconductor layer SC before the gate metal pattern GE is formed, and then the ion implantation process may be performed for doping the elements into the second region R2 of the oxide semiconductor layer SC to form a low-concentration doped region, thereby adjusting the impedance of the second region R2. By adjusting and increasing the impedance of the second region R2 of the oxide semiconductor layer SC, the second region R2 may achieve the function of voltage dispersion, thereby improving the withstand voltage performance of the transistor TR.

From the above description, according to the transistors of the embodiments of the present disclosure, through the specific layer-stacking design, such as disposing the field induced metal pattern, the width design of the field induced metal pattern, the distance design that the first distance is less than the second distance, the thickness design that the first thickness is greater than the second thickness and/or doping elements by ion implantation, the impedance of the second region of the oxide semiconductor layer may be adjusted and increased, so that the second region R2 may achieve the function of voltage dispersion, thereby improving the withstand voltage performance of the transistor.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A transistor, comprising:
a substrate;
an oxide semiconductor layer disposed on the substrate and comprising a first region, a second region and a third region, the second region being disposed between the first region and the third region, wherein when the transistor is turned off, an impedance of the first region is greater than an impedance of the second region, and the impedance of the second region is greater than an impedance of the third region;
a gate metal pattern disposed on the substrate and overlapped with the first region;
a source metal pattern or a drain metal pattern disposed on the oxide semiconductor layer and overlapped with the third region; and
a field induced metal pattern disposed on the substrate, wherein the field induced metal pattern is overlapped with the second region and not overlapped with the first region.

2. The transistor according to claim 1, wherein a width of the field induced metal pattern in a direction is less than a width of the gate metal pattern in the direction.

3. The transistor according to claim 1, wherein a width of the field induced metal pattern in a direction is greater than or equal to a width of the gate metal pattern in the direction.

4. The transistor according to claim 3, wherein a ratio of the width of the field induced metal pattern to the width of the gate metal pattern is greater than or equal to 1 and less than or equal to 2.

5. The transistor according to claim 1, wherein the field induced metal pattern is electrically isolated from the oxide semiconductor layer, and the field induced metal pattern receives a voltage when the transistor is turned on.

6. The transistor according to claim 5, wherein when the transistor is turned on, the impedance of the second region is greater than or equal to the impedance of the first region, and the impedance of the first region is greater than the impedance of the third region.

7. The transistor according to claim 1, wherein an ion doping concentration of the third region is greater than or equal to an ion doping concentration of the second region, and the ion doping concentration of the second region is greater than an ion doping concentration of the first region.

8. The transistor according to claim 1, wherein the oxide semiconductor layer is disposed between the substrate and the field induced metal pattern.

9. The transistor according to claim 8, wherein the field induced metal pattern comprises a transparent conductive material.

10. The transistor according to claim 1, wherein the field induced metal pattern is disposed between the substrate and the oxide semiconductor layer.

11. The transistor according to claim 1, wherein the gate metal pattern and the source metal pattern or the drain metal pattern are formed of a same conductive layer disposed on the oxide semiconductor layer.

12. A transistor, comprising:
a substrate;
an oxide semiconductor layer disposed on the substrate and comprising a first region, a second region and a third region, the second region being disposed between the first region and the third region, wherein when the transistor is turned off, an impedance of the first region is greater than an impedance of the second region, and the impedance of the second region is greater than an impedance of the third region;
a gate metal pattern disposed on the substrate and overlapped with the first region and the second region; and
a source metal pattern or a drain metal pattern disposed on the oxide semiconductor layer and overlapped with the third region,
wherein a minimum distance between the first region of the oxide semiconductor layer and the gate metal pattern is defined as a first distance, a minimum distance between the second region of the oxide semiconductor layer and the gate metal pattern is defined as a second distance, and the first distance is less than the second distance.

13. The transistor according to claim 12, wherein the first distance is greater than or equal to 500 angstroms and less than or equal to 3000 angstroms, the second distance is greater than 500 angstroms and less than or equal to 5000 angstroms, and a ratio of the first distance to the second distance is greater than or equal to 0.1 and less than 1.

14. The transistor according to claim 12, wherein a width of the first region is greater than or equal to a width of the second region.

15. The transistor according to claim 12, further comprising an insulating layer disposed between the oxide semiconductor layer and the gate metal pattern, wherein a thickness of a portion of the insulating layer overlapped with the first region is less than a thickness of another portion of the insulating layer overlapped with the second region.

16. The transistor according to claim 12, further comprising a conductive layer disposed between the substrate and the oxide semiconductor layer, wherein the conductive layer is overlapped with the first region of the oxide semiconductor layer and a portion of the gate metal pattern.

17. A transistor, comprising:
a substrate;
an oxide semiconductor layer disposed on the substrate and comprising a first region, a second region and a third region, the second region being disposed between the first region and the third region, wherein when the transistor is turned off, an impedance of the first region is greater than an impedance of the second region, and the impedance of the second region is greater than an impedance of the third region;
a gate metal pattern disposed on the oxide semiconductor layer and overlapped with the first region; and
a source metal pattern or a drain metal pattern disposed on the oxide semiconductor layer and overlapped with the third region,
wherein the first region of the oxide semiconductor layer has a first thickness, the second region of the oxide semiconductor layer has a second thickness, and the first thickness is greater than the second thickness.

18. The transistor according to claim 17, wherein the first thickness is greater than or equal to 50 angstroms and less than or equal to 500 angstroms, the second thickness is greater than or equal to 5 angstroms and less than or equal to 50 angstroms, and a ratio of the first thickness to the second thickness is greater than or equal to 1 and less than or equal to 100.

19. The transistor according to claim 17, wherein the third region of the oxide semiconductor layer has a third thickness, and the third thickness is greater than or equal to the second thickness.

20. The transistor according to claim 17, further comprising an insulating layer disposed between the gate metal pattern and the oxide semiconductor layer, wherein the insulating layer is overlapped with the first region and not overlapped with the second region nor the third region.
